(19) United States
(12) Patent Application Publication
(10) Pub. No.: US 2003/0123585 A1
(43) Pub. Date: Jul. 3, 2003

(54) Receiver with DFE and viterbi algorithm for block code transmission

(76) Inventor: Kuang-Yu Yen, TaiChung (TW)

Correspondence Address: Raymond Sun, 12420 Woodhall Way, Tustin, CA, 92782, US

(21) Appl. No.: 10/324,574

(22) Filed: Dec. 19, 2002

(30) Foreign Application Priority Data
Dec. 28, 2001 (TW) 90133480

(51) Int. Cl. H04B 1/10; H04L 25/08; H03D 1/06; H03K 5/01

(52) U.S. Cl. 375/350; 375/341; 375/348

(57) ABSTRACT

The present invention generally relates to block code transmission receiver and method, and uses Viterbi Algorithm to generate correct block signal. The receiver of the present invention comprises a Feed-Forward Equalizer (FFE) for receiving block signal and converting the block signal into a first signal with minimum phase; an Inter-Symbol Interference (ISI) eliminator for receiving the first signal and a feedback signal and the feedback signal is used to eliminate the Inter-Symbol Interference of the first signal, and the Inter-Symbol Interference (ISI) eliminator also generates a second signal without Inter-Symbol Interference; a Viterbi decoder for receiving the second signal and applying Viterbi Algorithm to generate a third signal; a block selecting device for receiving the third signal and generating the block code for transmission; and a Feedback Equalizer (FBE) for receiving the block code and generating a feedback signal.

### BACKGROUND OF THE INVENTION

1. Field of the Invention

The present invention generally relates to block code transmission receiver and method, and more particularly to receiver and method that use Feed-Forward Equalizer (FFE) to convert block signal into a signal with minimum phase, and further use Viterbi Algorithm to generate proper signal.

2. Description of the Prior Art

In recent years, continuous requirements for high-speed communication products have become major object for many projects in IEEE802.11 Committee, one of them is how to use the new standard of 2.4 GHz within the frequency spectrum. Wherein FCC Part 15.247 uses spread spectrum techniques to transmit the packet of data over 10 Mbps. However, IEEE802.11 Committee only involves in data transmission with the speed between 1 Mbps to 2 Mbps with technology of Frequency Hopping (FH) or Direct Sequence (DS) Spread Spectrum (SS), while IEEE802.11b has established the transmission standard of Complementary Code Keying (CCK) that transmits data over 11 Mbps. It adopts the original property of Spread Spectrum (SS) to comply with FCC requirement for Spread Spectrum signaling, with the new technology for receiver and by decreasing average spectrum density of transmission, it increases the robustness of the signal to against inadvertence interference. In addition, the new technology for receiver uses spectral redundancy to eliminate self-interference created by multipath distortion. However, extra equalizer is needed for modulation for 11 Mbps CCK in order to improve the performance.

FIG. 1 is illustrating the structure of a common receiver that meets the requirement of IEEE802.11 CCK. As shown, the receiver 10 receives the block signal transmitted from a transmitter (not shown), and the block signal is further processed by a Channel Matched Filter (CMF) 11 to improve S/N ratio. Next, the block signal will be processed by Feed-Forward Equalizer (FFE) 12, Inter-Symbol Interference (ISI) eliminator 13 and Feedback Equalizer (FBE) 15 to eliminate inter-symbol interference. Finally, the receiver will identify what the signal is with a slicer 14.

Although the receiver 10 uses the Channel Matched Filter (CMF) 11 to increase the S/N ratio of the block signal, however, the channel path is also increased. Moreover, if the original channel response is with minimum phase, after the Channel Matched Filter (CMF) 11, the channel response will become to be with non-minimum phase, which will cause the length of Feedback Equalizer (FBE) 15 increase and the convergence of FBE become worse. Especially, in the wireless environment that the S/N ratio is bad, the Feedback Equalizer (FBE) 15 often converges to wrong settings; so, whatever long packet or short packet will not be received properly.

### SUMMARY OF THE INVENTION

Accordingly, it is the primary object of the present invention to provide receiver and method that are able to receive the Block Code properly.

To achieve the foregoing object, the receiver of the present invention comprises a Feed-Forward Equalizer for receiving block signal and converting the block signal into a first signal with minimum phase; an Inter-Symbol Interference (ISI) eliminator for receiving the first signal and a feedback signal and the feedback signal is used to eliminate the Inter-Symbol Interference of the first signal, and the eliminator also generates a second signal not having Inter-Symbol Interference; a Viterbi decoder for receiving the second signal and applying Viterbi Algorithm to generate a third signal; a block selecting device for receiving the third signal and generating the transmitted block signal; and a Feedback Equalizer (FBE) for receiving the block and generating a feedback signal.

Other and further features, advantages and benefits of the invention will become apparent in the following description taken in conjunction with the following drawings. It is to be understood that the foregoing general description and following detailed description are exemplary and explanatory but are not to be restrictive of the invention. The accompanying drawings are incorporated in and constitute a part of this application and, together with the description, serve to explain the principles of the invention in general terms. Like numerals refer to like parts throughout the disclosure.

### BRIEF DESCRIPTION OF THE DRAWINGS

The objects, spirits and advantages of the preferred embodiments of the present invention will be readily understood by the accompanying drawings and detailed descriptions, wherein:

FIG. 1 is a diagram showing the structure of a conventional receiver in accordance with the prior art.

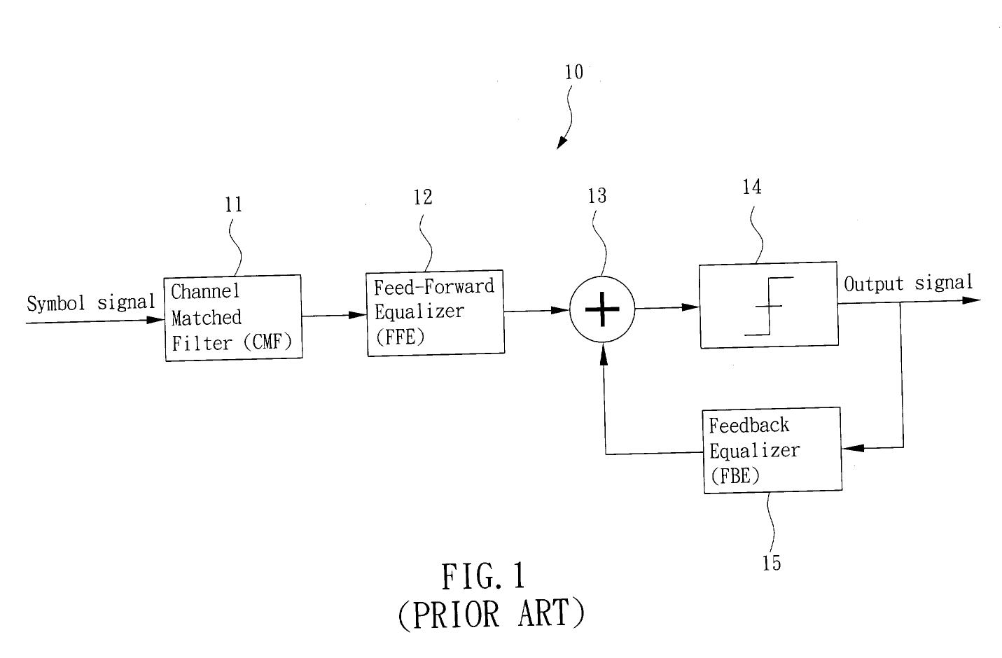

FIG. 2 is a diagram showing that the signal has been divided into a plurality of blocks, and known symbols have been inserted into between blocks.

FIG. 3 is a diagram showing a signal without the interference from precursor.

FIG. 4 is a diagram showing that the signal has been divided into a plurality of blocks, but known symbols have not been inserted into between blocks.

FIG. 5 is a diagram showing the structure of the receiver of the present invention.

FIG. 6 is a diagram showing the relationship among received signal ┌r0˜r7┘, current received symbol ┌C0˜C7┘, channel response ┌h0˜h7┘ and noise ┌n0˜n7┘.

FIG. 7 is a schematic block diagram for Viterbi decoder.

FIG. 8 is a schematic block diagram for the method for receiving block code of the present invention.

### DETAILED DESCRIPTION OF THE INVENTION

The present invention providing a receiver and a method for receiving block code can be exemplified by the preferred embodiment as described hereinafter.

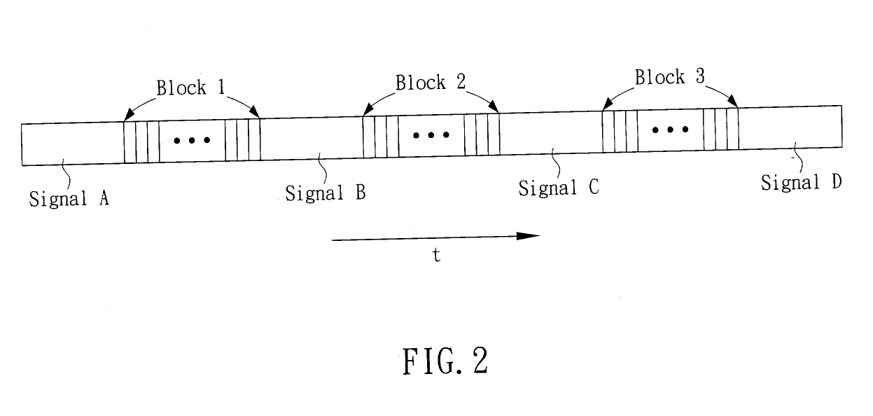

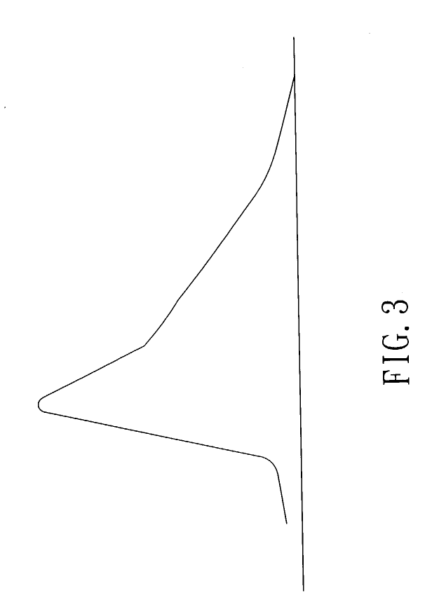

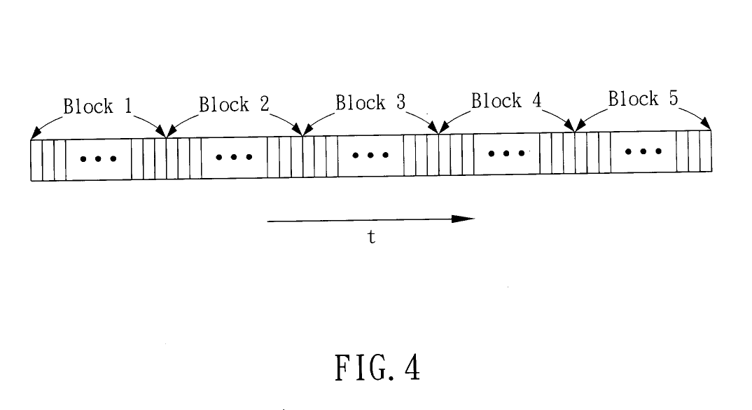

FIG. 2 is illustrating that the signal has been divided into a plurality of block signals for transmission. As shown in FIG. 2, known symbol inserted between block signals will reduce the interference within, and the receiver will receive the signal properly only by eliminating the interference, which will not just simplify the design of receiver but also increase the receiving capability of the receiver. FIG. 3 is illustrating that, in an indoor wireless communication environment, the channel response is often with minimum phase and there is less pre-cursor interference. That means the known symbol signal B will not interfere the signal block 1, the known symbol signal C will not interfere the signal block 2, and the known symbol signal D will not interfere the signal block 3. Thus, if the receiver is able to eliminate the Inter-Symbol Interference (ISI) created by the previous signal block interfering to the incoming signal block by adding (or deducting) the received signal block based on the signal block being detected, the known symbol will not be transmitted to save bandwidth, as shown in FIG. 4.

The same idea can apply to the modulation technology for IEEE802.11b Complementary Code Keying (CCK); similar signal transmission is shown in FIG. 4. In FIG. 4, the interference that signal block 1 interfering the signal block 2 can be eliminated first, and then the signal included in the signal block 2 will be resolved properly, so, the known symbol signals will be no more transmitted to save bandwidth. In the modulation technology for IEEE802.11b Complementary Code Keying (CCK), each block in FIG. 4 will be regarded as a Symbol, and every Symbol includes 8 Quadrature Phase Shift Keying (QPSK) signal and every QPSK signal can be regarded as a Chip, that is, every Block (or Symbol) includes 8 Chips.

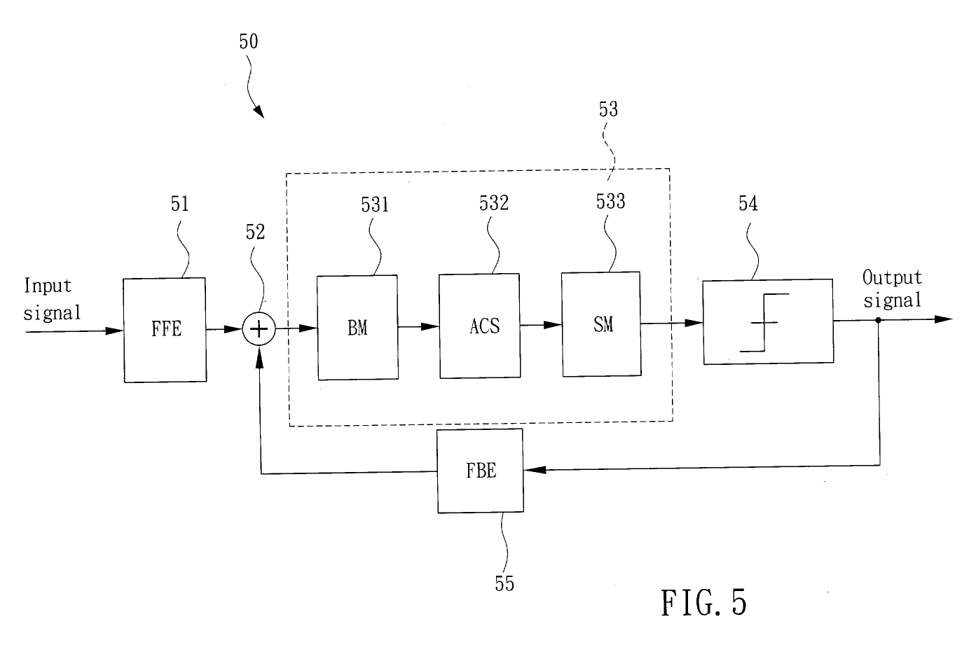

Please refer to FIG. 5, which is a diagram showing the structure of the receiver of the present invention. As shown, the receiver 50 of the present invention comprises a Feed-Forward Equalizer (FFE) 51, an Inter-Symbol Interference (ISI) eliminator 52, a Viterbi Decoder 53, a block selecting device 54 and a Feedback Equalizer (FBE) 55.

In the present invention, the signal is transmitted in the form of block code. The receiver 50 uses the Feed-Forward Equalizer (FFE) 51 to make the whole channel have the property of minimum phase, and generate a first signal. A few parameters are involved for setting up the Feed-Forward Equalizer (FFE) 51. For example, if the Channel Response is ┌1+1j, 2+2j, 0.5+0.5j┘, the 2+2j will be the Main-Path Response, the 1+1j will be the Pre-cursor Response and the 0.5+0.5j will be the Post-cursor Response. The parameter of the Feed-Forward Equalizer (FFE) 51 can be set up to ┌2−2j, 1−1j┘, then the Channel Response behind the Feed-Forward Equalizer (FFE) 51 will be ┌2,8,9,2┘. Next, the system will set up ┌8┘ as the Main-Path Response, ┌2┘ will be the Pre-cursor Response and ┌9,2┘ will be the Post-cursor Response. Therefore, the ratio of the Pre-cursor over the Main-Path can be enlarged by square times (e.g. ½ to ¼). Then, the parameter of the Feed-Forward Equalizer (FFE) 51 will be set up to be the conjugate number of the Main-Path of the Channel Response to reduce the intensity of the Feed-Forward Interference. Of course, the parameters of the Feed-Forward Equalizer (FFE) 51 can be set up properly by zero-forcing criterion or by minimum mean square error (MMSE) criterion. After modified by the Feed-Forward Equalizer (FFE) 51, the first signal is only interfered by the signal received previously. The first signal therefore become the received signal and is defined as ┌R0˜R7┘, and the relationship among the first signal ┌R0˜R7┘, the current received symbol ┌C0˜C7┘, the previous received symbol ┌B0˜B7┘, the channel interference response ┌h0˜h7┘ and the noise ┌n0˜n7┘ will be formulated as follows:

R0=C0*h0+B7*h1+B6*h2+B5*h3+B4*h4+B3*h5+B2*h6+B1*h7+n0.

R1=C1*h0+C0*h1+B7*h2+B6*h3+B5*h4+B4*h5+B3*h6+B2*h7+n1.

R2=C2*h0+C1*h1+C0*h2+B7*h3+B6*h4+B5*h5+B4*h6+B3*h7+n2.

R7=C7*h0+C6*h1+C5*h2+C4*h3+C3*h4+C2*h5+C1*h6+C0*h7+n7.

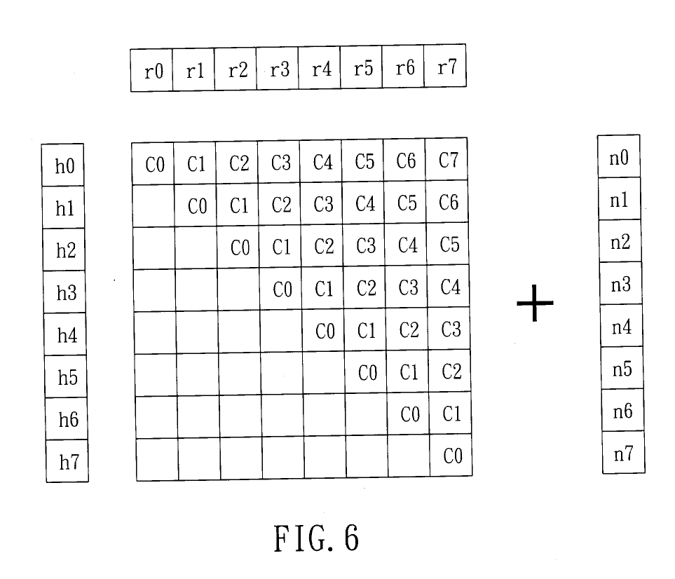

The Inter-Symbol Interference (ISI) of the first signal ┌R0˜R7┘ can be eliminated by the Inter-Symbol Interference (ISI) eliminator 52 and a second signal ┌r0˜r7┘ will be generated. The Inter-Symbol Interference (ISI) eliminator 52 mainly eliminates the interference between the previous-received symbol and the current received signal (the first signal). Since the channel has become being with minimum phase after processed by the Feed-Forward Equalizer (FFE) 51, simple mathematic operation such as addition or deduction will be employed to modify the signal. Obtaining the parameters of ISI eliminator 52 can be achieved by estimating the channel response after the process of the Feed-Forward Equalizer (FFE) 51. Since the interference that created by the previous received symbol ┌B0˜B7┘ interfering the first signal ┌R0˜R7┘ has been eliminated by the Inter-Symbol Interference (ISI) eliminator 52, the second signal ┌r0˜r7┘ only comprises the current received symbol ┌C0˜C7┘, the channel interference response ┌h0˜h7┘ and the noise ┌n0˜n7┘. As illustrated in FIG. 6, the second signal ┌r0˜r7┘ the current received symbol ┌C0˜C7┘, the channel response ┌h0˜h7┘ and the noise ┌n0˜n7┘ can be formulated as follows:

r0=C0*h0++n0

r1=C1*h0+C0*h1+n1

r2=C2*h0+C1*h1+C0*h2+n2

r7=C7*h0+C6*h1+C5*h2+C4*h3+C3*h4+C2*h5+C1*h6+C0*h7+n7

In order to resolve the current received symbol ┌C0˜C7┘ more efficiently, the present invention uses Viterbi decoder 53 to recover the current received symbol ┌C0˜C7┘.

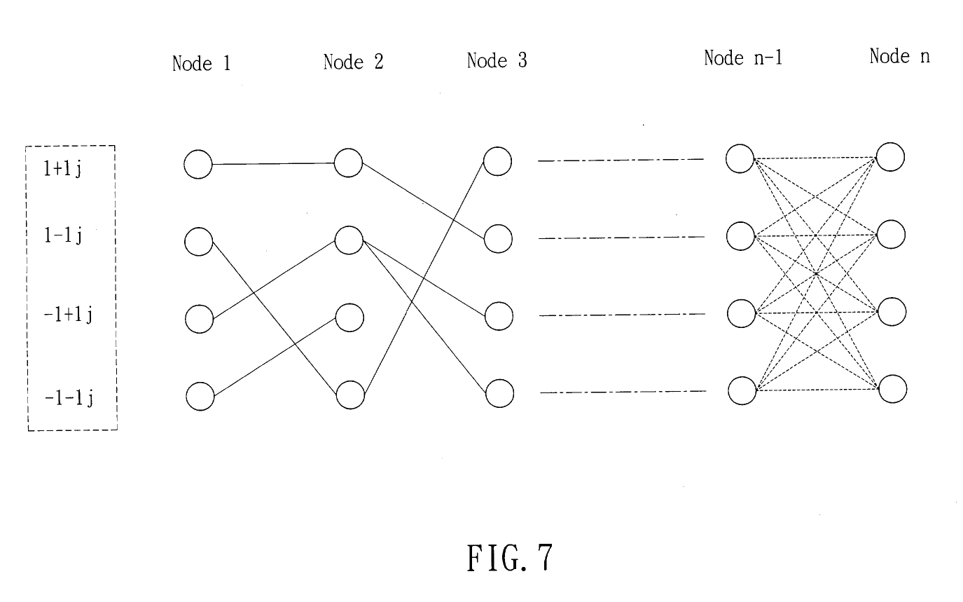

FIG. 7 is a schematic block diagram showing how Viterbi decoder 53 eliminating Inter-Chips Interference (ICI). Taking 802.11b of Wireless Local Area Network (WLAN) as example, the schematic block diagram that Viterbi decoder 53 eliminating Inter-Chips Interference (ICI) can be represented by 4 state trellis diagram. These 4 states represent the value of Quadrature Phase Shift Keying (QPSK) with 90-degree phase difference respectively, that is, (1+j, 1−j, −1+j, −1−j). When processing, node 1 creates 4 branches corresponding 4 states for next node. The branch metric for each branch can be calculated and the minimum branch metric will be selected as the survival branch. The following shows the formula for calculating the branch metric.

$${metric}_{k} = {metric}_{k - 1} + \vert {\sum }_{i = 1}^{k} {\hat{s}}_{i} \cdot {h}_{k - i} - {r}_{k} \vert \qquad Formula ( 1 )$$

Wherein (change to→)hₖ₋ᵢ is the channel interference response, rₖ is the second signal, Ŝ_{i(l≦i≦k-l)} is the detected value, (change to→)Ŝᵢ₍ᵢ₌ₖ₎ is the value of node. Therefore, all the branch metric for a particular node can be calculated, and the survival branch path and the branch metric thereof reaching to this particular node can be allocated. In this embodiment, the maximum value of k is 8. So, every time when a signal being received, the latest branch metric reaching to every node will be calculated and the branch path will be recorded till the whole block signal being received completely. Finally, adopting the signal of the branch with the minimum branch metric, the best block will be allocated by the block selecting device 54. The allocated block then will be feedback to the Feedback Equalizer (FBE) 55 to eliminate the Inter-Symbol Interference (ISI) for next block. This method can apply on WLAN 802.11B as well as the block code transmitted in Minimum Phase Channel.

As shown in FIG. 5, the Viterbi decoder comprises a Branch Metric (BM) 531, an Add-Compare Select (ACS) 532, and a Survival Metric (SM) 533. The Branch Metric (BM) 531 is responsible for the calculation of the branch metric

$$( \vert {\sum }_{i = 1}^{k} {\hat{s}}_{i} \cdot {h}_{k - i} - {r}_{k} \vert )$$

from the last branch to the next node. The Add-Compare Select (ACS) 532 will add every branch metric to the node with the last branch metric and select a minimum branch metric (allocating Ŝ_{i(l≦i≦k)} and metricₖ) as the survival branch metric. The Survival Metric (SM) 533 will record the survival branch metric for each node and the corresponding branch signal.

In WLAN 802.11b, after decoding by the Viterbi decoder, 8 QPSK signals will be obtained. These signals could still contain some error codes, therefore, the signal generated by the Viterbi decoder can be sent to the next level block selecting device to allocate the most possible block for the best output block.

With the method, the correct block can be obtained by the Viterbi decoder and the property of the block code, after then, the interference to the next block code can be reduced. So, the received signal only contain the Inter-Chips Interference within the block, and the Inter-Chips Interference can be eliminated by a simple Viterbi decoder again to obtain the best block by the block selecting device. Meanwhile, the memory space needed for the Viterbi decoder is the length of the block code. For example, in IEEE 802.11b, every block only contains 8 QPSK signals. When receiving a new block, the whole Viterbi decoder will be reset and the memory it occupied will be refreshed.

Moreover, in a different embodiment, when the arrangement of the block code is in a certain format; meaning that some kind of correlation exist when the signal of the blocks transmitting, the selection of block still can be completed by the Branch Metric (BM) 531 of the Viterbi decoder. When the Branch Metric (BM) 531 completed the calculation for the branch metric for one branch to one next node, with the certain format of the block code arrangement, the unreasonable branch metric will be eliminated directly. Therefore, the block selected by the Survival Metric (SM) 533 is the best received block.

The correctness of the Viterbi decoder can be increased by the correlation existing in the block, that is, the Viterbi Algorithm will adopt the correlation of the block code to eliminate the less possible branch first when selecting the best branch. For example, in WLAN 802.11b, 8 QPSK signals will have 4⁸ different combinations, however, only 2⁸ of them will be transmitted, the rest does not exist. So, the Branch Metric (BM) 531 of the Viterbi decoder will eliminate the less possible combinations. For instance, the block in 802.11b, after transmitting the chips (1+1j, 1+1j, 1+1j), the possible chip for transmitting is (−1−1j), other possible chip (1+1j or −1+1j or 1−1j) does not exist.

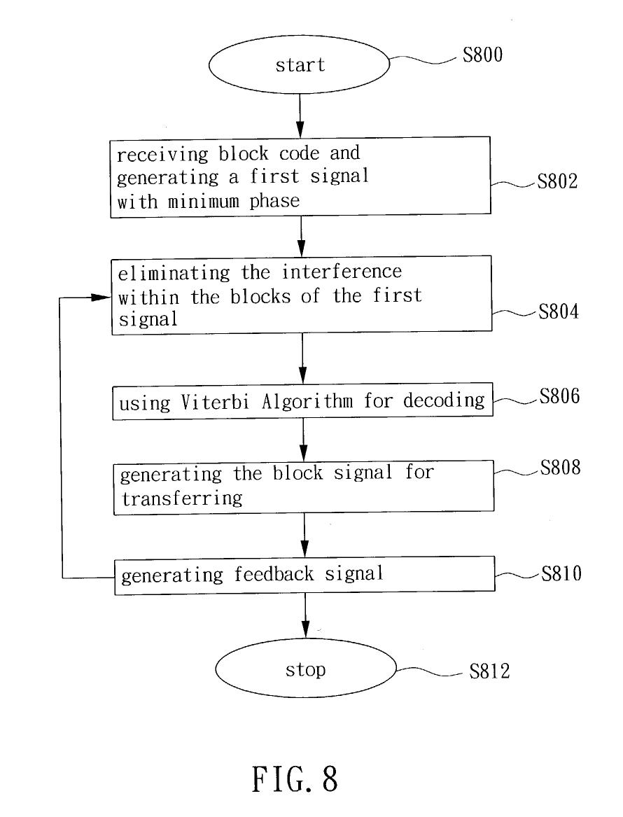

FIG. 8 is a schematic block diagram of the method of receiving block code of the present invention, which comprises the steps of:

step S800 of start;

step S802 of generating signal with minimum phase, which is using Feed-Forward Equalizer (FFE) for receiving block code and generating a first signal with minimum phase;

step S804 of eliminating interference between blocks, which is receiving the first signal and a feedback signal that is used for eliminating the interference within the blocks of the first signal, and generating a second signal without block interference, the method used in this step is to deduct the first signal from the feedback signal to obtain the second signal without block interference;

step S806 of decoding block, which is receiving the second signal, and using Viterbi Algorithm to generate the third signal;

step S808 of selecting block, which is receiving the third signal and generating the transmitted block signal;

step S810 of generating feedback signal, which is receiving the block output from the block selecting device and generating the feedback signal with Feedback Equalizer (FBE).

step S812 of stop.

In addition, step S806 of decoding block includes the step of calculating branch metric, which calculating the branch metric from one branch to one node. Step of Add-Compare Select will add together the branch metric for each branch to one node and the last branch metric on the branch, and select the minimum branch metric. Step of Survival Metric will record the survival branch metric for each node and the corresponding branch signal.

In the step S806 of decoding block, the correctness of Viterbi decoding can be increased by correlation existing in the blocks, that is, the Viterbi Algorithm will adopt the correlation of the block code to eliminate the less possible branch first when selecting the best branch, therefore, the step of selecting block can be omitted.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A receiver for block code transmission, which comprising:
a Feed-Forward Equalizer (FFE) receiving block signal and converting the block signal into a first signal with minimum phase;
an Inter-Symbol Interference (ISI) eliminator receiving the first signal and a feedback signal that is used to eliminate the Inter-Symbol Interference of the first signal, and generating a second signal with no Inter-Symbol Interference;
a Viterbi decoder receiving the second signal and using Viterbi Algorithm to generate a transmitted block code; and
a Feedback Equalizer (FBE) receiving the block code output from the Viterbi decoder and generating the feedback signal.

2. The receiver of claim 1, wherein the Inter-Symbol Interference (ISI) eliminator is an adder.

3. The receiver of claim 1, wherein the Viterbi decoder comprises:
a Branch Metric (BM) device calculating a branch metric from one branch to next node;
an Add-Compare Select (ACS) device adding every branch metric to the node with the last branch metric and selecting a minimum branch metric as a survival branch metric.
a Survival Metric (SM) device recording the survival branch metric for each node, and recording the corresponding branch signal.

4. The receiver of claim 3, wherein the Branch Metric device can omit the unreasonable branch metric directly according to the correlation of block codes.

5. A receiver for block code transmission, which comprising:
a Feed-Forward Equalizer (FFE) receiving block signal and converting the block signal into a first signal with minimum phase;
an Inter-Symbol Interference (ISI) eliminator receiving the first signal and a feedback signal, and generating a second signal with no Inter-Symbol Interference;
a Viterbi decoder receiving the second signal and using Viterbi Algorithm to generate a third signal;
a block selecting device receiving the third signal and generating the transmitted block codes; and
a Feedback Equalizer (FBE) receiving the block code and generating the feedback signal.

6. The receiver of claim 5, wherein the Inter-Symbol Interference (ISI) eliminator is an adder.

7. The receiver of claim 5, wherein the Viterbi decoder comprises:
a Branch Metric (BM) device calculating a branch metric from one branch to next node;
an Add-Compare Select (ACS) device adding every branch metric to the node with the last branch metric and selecting a minimum branch metric as a survival branch metric.
a Survival Metric (SM) device recording the survival branch metric for each node, and recording the corresponding branch signal.

8. The receiver of claim 7, wherein the Branch Metric device can omit the unreasonable branch metric directly according to the correlation of block codes.

9. A method for block code transmission, which comprising the steps of:
generating signal with minimum phase, which is receiving a block signal and converting the block signal into a first signal with minimum phase;
eliminating interference between blocks, which is receiving the first signal and a feedback signal, and generating a second signal without block interference;
decoding block, which is receiving the second signal and using the Viterbi Algorithm to generate a transmitted block signal; and
generating feedback signal, which is receiving the block signal and generating the feedback signal.

10. The method of claim 9, wherein comprising a step of selecting block following the step of decoding block, the step of selecting block is for receiving the output signal from the step of decoding block and generating the transmitted block signals.

11. The method of claim 9, wherein the step of eliminating interference minus the first signal from the feedback signal.

12. The method of claim 10, wherein the step of eliminating interference minus the first signal from the feedback signal.

13. The method of claim 9, wherein the step of decoding block comprising:
a step of calculating Branch Metric for calculating branch metric from one branch to next node;
a step of adding, comparing and selecting for adding every branch metric to the node with the last branch metric and selecting a minimum branch metric as a survival branch metric;
a step of calculating Survival Metric for recording the survival branch metric for each node, and recording the corresponding branch signal.

14. The method of claim 13, wherein the step of calculating Branch Metric comprising a step of omitting unreasonable branch metric, which omits the unreasonable branch metric according to the correlation of block codes.

15. The method of claim 10, wherein the step of decoding block comprising:
a step of calculating Branch Metric for calculating branch metric from one branch to next node;
a step of adding, comparing and selecting for adding every branch metric to the node with the last branch metric and selecting a minimum branch metric as a survival branch metric;
a step of calculating Survival Metric for recording the survival branch metric for each node, and recording the corresponding branch signal.

16. The method of claim 15, wherein the step of calculating Branch Metric comprising a step of omitting unreasonable branch metric, which omits the unreasonable branch metric according to the correlation of block codes.
